(19) United States
(12) Patent Application Publication
(10) Pub. No.: US 2020/0308452 A1
(43) Pub. Date: Oct. 1, 2020

(54) Low Temperature Mechanical Polishing Or Planarization Slurry For Surfactant Solubility

(71) Applicant: Versum Materials US, LLC, Tempe, AZ (US)

(72) Inventors: Maitland G. Graham, Chandler, AZ (US); James Allen Schlueter, Phoenix, AZ (US)

(73) Assignee: Versum Materials US, LLC, Tempe, AZ (US)

(21) Appl. No.: 16/874,285

(22) Filed: May 14, 2020

(51) Int. Cl. C09G 1/02

(52) U.S. Cl. CPC C09G 1/02; H01L 21/3212

(57) ABSTRACT

A novel process to make chemical mechanical planarization alkaline barrier slurries has been disclosed. The process provides the ability to solubilize surfactants comprise block co-polymers with low HLB numbers into the alkaline barrier slurries.

### BACKGROUND

This invention pertains to slurries (or polishing compositions), and methods of making slurries used for Chemical Mechanical Polishing or Planarization (CMP) of semiconductor devices, particularly for alkaline barrier slurries.

Usually, a barrier layer covers the patterned dielectric layer and a metal layer covers the barrier layer. The metal layer has at least sufficient thickness to fill the patterned trenches with metal to form circuit interconnects.

A barrier typically is a metal, metal alloy or intermetallic compound, such as tantalum or tantalum nitride. The barrier forms a layer that prevents migration or diffusion between layers within a wafer. For example, barriers prevent the diffusion of interconnect metal such as copper or silver into an adjacent dielectric. Barrier materials must be resistant to corrosion by most acids, and thereby, resist dissolution in a fluid polishing composition for CMP. Furthermore, these barrier materials may exhibit a toughness that resists removal by abrasion abrasive particles in a CMP slurry and from fixed abrasive pads.

In relation to CMP, the current state of this technology involves the use of a multi-step, such as, a two-step process to achieve local and global planarization.

During step 1 of a CMP process, metal layer such as the overburden copper is removed, while leaving a smooth planar surface on the wafer with metal-filled lines, vias and trenches that provide circuit interconnects planar to the polished surface. First step polishing steps tend to remove excess interconnect metals, such as copper. Then step 2 of the CMP process, frequently referred to as a barrier CMP process, follows to remove the barrier layer and excess metal layers and other films on the surface of the patterned wafers to achieve both local and global planarization surface on the dielectric layer.

Barrier slurry compositions need to meet several stringent requirements including high barrier removal rates, very low post-polish topography, no corrosion defects and very low scratches or residue defects. Therefore, there are significant needs for barrier CMP compositions, CMP process(es) or methods when these requirements become more and more stringent as the semiconductor industry continues to move towards smaller and smaller feature sizes.

CMP slurries may contain block co-polymers surfactants that have a hydrophobic, polypropylene oxide (PO), segment bookended by two hydrophilic polyethylene oxide (EO) segments. There is a problem to solubilize the surfactants into a CMP formulation during the manufacturing process, especially for alkaline barrier CMP barriers.

There still has been a need for a novel process to make CMP alkaline barrier slurries that can solubilize the surfactants.

### SUMMARY

The present invention relates to a method of making CMP slurries used for Chemical Mechanical Polishing or Planarization (CMP) of semiconductor devices, particularly for alkaline barrier slurries containing block co-polymers surfactants that have a hydrophobic, polypropylene oxide (PO), segment bookended by two hydrophilic polyethylene oxide (EO) segments.

In one aspect, described herein is a method for making a barrier chemical mechanical planarization polishing composition, comprising:
providing water;
providing at least one constituent selected from the group consisting of pH adjuster;
oxidizing agent; corrosion inhibitor; biocide, and chelator;
adding the at least one constituent into the water to obtain a first mixture, providing abrasive;
providing a block co-polymers surfactant that have a hydrophobic, polypropylene oxide (PO), segment bookended by two hydrophilic polyethylene oxide (EO) segments;
adding the abrasive and the block co-polymers surfactant into the mixture to obtain a second mixture;
filtering the second mixture with filters having a pore size of ≤1 μm, 0.5 μm, or 0.1 μm to obtain the chemical mechanical planarization polishing composition for packaging;
wherein the abrasive and waster are having a low starting temperature to make the block co-polymers surfactant 100% solubilized in the chemical mechanical planarization polishing composition; and
pH of the polishing composition is between 2 to 14, 4 to 12, 9 to 11.5; or 10 to 11.

### BRIEF DESCRIPTION OF THE SEVERAL VIEWS OF THE DRAWING

The present invention will hereinafter be described in conjunction with the appended figures wherein like numerals denote like elements:

FIG. 1 shows Pluronic® L61 concentration (wt. %) in alkaline barrier Pails slurry vs Totes slurry.

FIG. 2 shows Pluronic® L61 concentration (wt. %) in an alkaline barrier slurry when filtered at different temperatures.

FIG. 3 shows the turbidity of an alkaline barrier slurry with Pluronic® L61 vs temperature.

FIG. 4 shows the re-circulation test for an alkaline barrier slurry with Pluronic® L61 at 23° C. and 26° C.

FIG. 5 shows the alkaline barrier slurry and “cold” Small Volume Manufacturing (SVM) temperature profile.

FIG. 6 shows Pluronic® L61 concentration in an alkaline barrier Pails slurries vs Totes slurries vs “cool process” Totes slurries.

### DETAILED DESCRIPTION

The present invention relates to a method of making CMP slurries used for Chemical Mechanical Polishing or Planarization (CMP) of semiconductor devices, particularly for alkaline barrier slurries containing block co-polymers surfactants that have a hydrophobic, polypropylene oxide (PO), segment bookended by two hydrophilic polyethylene oxide (EO) segments.

In one aspect, described herein is a method for making a barrier chemical mechanical planarization polishing composition, comprising:
providing water;
providing at least one constituent selected from the group consisting of pH adjuster; oxidizing agent; corrosion inhibitor; biocide, and chelator;
adding the at least one constituent into the water to obtain a first mixture, providing abrasive;
providing a block co-polymers surfactant that have a hydrophobic, polypropylene oxide (PO), segment bookended by two hydrophilic polyethylene oxide (EO) segments;
adding the abrasive and the block co-polymers surfactant into the mixture to obtain a second mixture;
filtering the second mixture with filters having a pore size of 1 μm, 0.5 μm, or 0.1 μm to obtain the chemical mechanical planarization polishing composition for packaging;
wherein the abrasive and waster are having a low starting temperature to make the block co-polymers surfactant 100% solubilized in the chemical mechanical planarization polishing composition; and
pH of the polishing composition is between 2 to 14, 4 to 12, 9 to about 11.5; or 10 toll.

Water can be a deionized water, distilled water, et al.

The block co-polymers surfactants can be any surfactant that contains block co-polymers. Examples includes but is not limited to Pluronic® L family which contains—Poly(ethylene glycol)-block-poly(propylene glycol)-block-poly(ethylene glycol). The Pluronic® L family is from Millipore Sigma at St. Louis, Mo.

Those block co-polymers surfactants have a hydrophobic, polypropylene oxide (PO), segment bookended by two hydrophilic polyethylene oxide (EO) segments. The hydrophobicity or hydrophilicity, represented by the hydrophilic lithophilic balance (HLB) number, of a surfactant can be changed by increasing or decreasing the lengths of either segment of the molecule. Block co-polymers with low HLB numbers benefit the performance of an alkaline barrier slurry in several ways: 1) they are capable of suppressing the removal rate of low k dielectrics, 2) provide excellent wetting properties to the slurry which in turn can result in lower mechanical defects and 3) have anti foaming properties.

The table below highlights a few examples of such surfactants.

TABLE I
Pluronic ®L family with cloud points near 25° C.

| | | Cloudpoint (° C., | | |
|---|---|---|---|---|
| Name | MW | 1% Aqueous sln) | HLB | Structure |
| Pluronic L61 | 2000 | 24 | 3 | EO-PO-EO |
| Pluronic L81 | 2800 | 20 | 2 | EO-PO-EO |
| Pluronic L62 | 2500 | 32 | 7 | EO-PO-EO |
| Pluronic 31R1 | 3250 | 25 | 1 | PO-EO-PO |

The ability to solubilize such surfactants into a CMP slurry will also depend on the desired concentration of the surfactant in the CMP slurry. For example, L81 has the lowest cloud point so an acceptable finished concentration would have to be significantly less than 1% by weight. The opposite is true for L62 where it could be added at a significantly higher concentration than 1% due to its higher cloud point.

The abrasive can be any abrasive that is suitable for barrier polishing.

Example of abrasive is selected from the group consisting of colloidal silica, alumina, ceria, germania, silica, titania, zirconia, alumina dopes colloidal silica in lattices, organic polymer particles, composite particles of inorganic and organic particles, surface modified inorganic/organic particles, and combinations thereof; and in an amount ranging from about 0.1% to about 15 wt. %; preferably from about 1 wt. % to about 3 Wt. %.

The oxidizing agent is selected from the group consisting of hydrogen peroxide, periodic acid, potassium iodate, potassium permanganate, ammonium persulfate, ammonium molybdate, ferric nitrate, nitric acid, potassium nitrate, ammonia, amine compounds, and combinations thereof; and in an amount ranging from about 0.05 wt. % to about 10 wt. %; preferably from about 0.5 wt. % to about 2 wt. %.

The corrosion inhibitor is selected from the group consisting of benzotriazole or benzotriazole derivatives, 3-amino-1,2,4-triazole, 3,5-diamine-1,2,4-triazole, and combinations thereof; and in an amount ranging from about 0.001 wt. % to about 1.0 wt. %; preferably from about 0.01 wt. % to about 0.1 wt. %;

The chelator is selected from the group consisting of benzosulfonic acid, 4-tolyl sulfonic acid, 2,4-diamino-benzosulfonic acid, and etc., and also non-aromatic organic acids, such as itaconic acid, malic acid, malonic acid, tartaric acid, citric acid, oxalic acid, gluconic acid, lactic acid, mandelic acid, and combinations thereof; and in an amount ranging from about 0.01 wt. % to about 3.0 wt. %; preferably about from 0.4 wt. % to about 1.5 wt. %.

The pH adjustor selected from the group consisting of (a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and in an amount ranging from about 0.0001 wt. % to about 2 wt. %.

The biocide used in the CMP polishing slurry composition can be any biocide for example, a commercially available Kathon type biocide.

The methods of making polishing compositions described herein will be illustrated in more detail with reference to the following examples, but it should be understood that it is not deemed to be limited thereto.

### WORKING EXAMPLES

### General Experimental Procedure

All percentages are weight percentages unless otherwise indicated. In the examples presented below, CMP experiments were run using the procedures and experimental conditions given below.

### Example 1

Pluronic® L61 was used for the testing.

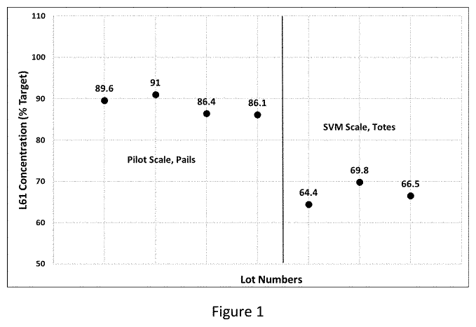

Initial High-Performance Liquid Chromatography (HPLC) Pluronic® L61 assay comparison between alkaline barrier slurry pilot plant lots (pails) vs Small volume manufacture (SVM) lots (totes) revealed a difference in concentration as shown in FIG. 1.

In FIG. 1, the totes showed a 30% to 35% decrease in Pluronic® L61 concentration compared to pail samples. A performance difference between pails and totes with the pail samples having the desired performance was observed.

Raw material lot comparison showed good commonality between the two sample types, so a bad Pluronic® L61 raw material lot was ruled out.

A factor that was considered was the temperature of the deionized water (DIW) used for both sample types. The DIW charged to the totes sample lots made was around 27° C. and the DIW measured temperature for one of pail sample lots was measured to be around 24° C.

The leading hypothesis for the missing Pluronic® L61: the elevated temperature of the totes sample lots was above the cloud point of the surfactant and therefore a percentage of the surfactant was insoluble and being removed by the filters during packaging.

A sample of alkaline barrier slurry was made without the abrasive. The sample was then placed in a water bath @ 35° C. for 2 hours and then removed from the water bath. The formulation turned cloudy after exposure to heat.

After it sat for 2 hrs at room temperature it became clear again.

This observation demonstrated how it could be possible to remove insoluble surfactant during filtration.

### Example 2

A sample of alkaline barrier slurry was made with DIW cooled by refrigeration. This was done to ensure that at the time of mixing the Pluronic® L61 with the rest of the formulation the surfactant would be completely solubilized. The sample was then split 6 ways, so it could be filtered at 6 different temperatures ranging from 15° C. to 35° C.

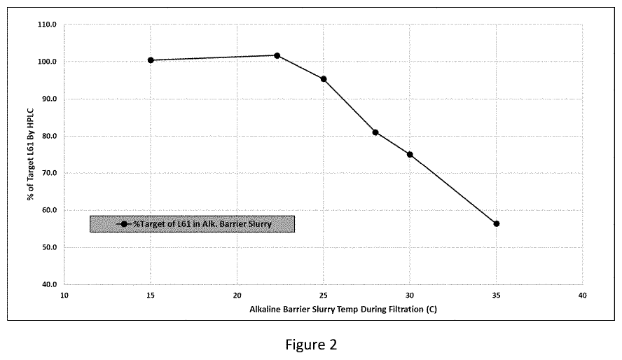

The Pluronic® L61 concentration in each sample was quantified via HPLC shown in FIG. 2.

This data showed that as the slurry temperature increases so does the loss of Pluronic® L61 during filtration. At 35° C., close to half of the surfactant has been removed from the filtered product. This curve also demonstrates why the alkaline barrier slurry SVM had more loss (around 30%) than the pail samples (around 10%).

### Example 3

A turbidity test was conducted on the alkaline barrier slurry to determine a more accurate temperature where the Pluronic® L61 begins to become insoluble.

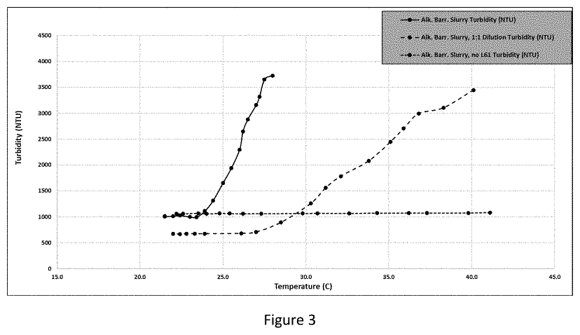

Alkaline barrier slurry with and without Pluronic® L61 were measured along with alkaline barrier slurry diluted 1:1 vs decreasing temperature as shown in FIG. 3.

Alkaline barrier slurries w/o Pluronic® L61 showed no increase in turbidity with increasing temperature and established a baseline of around 1030 turbidity units. Alkaline barrier slurries have a similar baseline turbidity up to a measured temperature of 23.4° C.

The next data point of 24° C. showed an increase in turbidity. This data gave the manufacturing process an upper temperature limit where Pluronic® L61 will start to become insoluble and could be removed from the slurry.

Alkaline barrier slurry was then re-circ filtered at two different temperatures with 0.1 μm filters to further define how Pluronic® L61 could be removed from the formulation. Here the alkaline barrier slurry was held at two different temperatures of 23° C. and 26° C. and re-circulated through the filters for 6 hours.

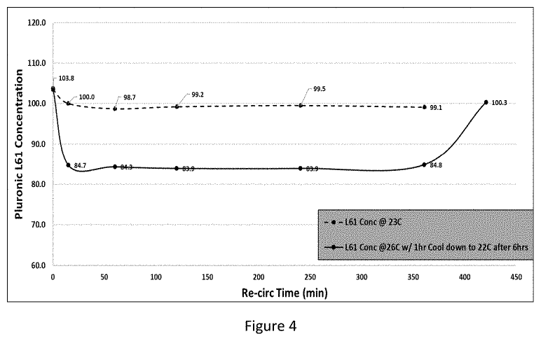

Sample was collected post filter at several time points to quantify via HPLC what happens to Pluronic® L61 at these two constant temperatures through a tighter filter with a long re-circ time as shown in FIG. 4.

At 23° C., the upper limit of the temp filtration specification, the Pluronic® L61 came back consistently near 100% assay during a 6 hr continuous re-circulation.

At 26° C., above the upper temperature limit, there was about a consistent 15% loss of Pluronic® L61 during 6 hrs of continuous re-circulation. It was decided to continue the re-circulation for a 7th hour but reducing the temperature of the sample to 22° C. for this last hour. The sample collected at the end of the 7th hour when the sample was reading 22° C. showed a full recovery of the Pluronic® L61.

This indicates that the insoluble Pluronic® L61 captured by the filter when the slurry temp was at 26° C. became soluble again when the temperature of the alkaline barrier slurry in the filter housing reached 22° C.

The reversible nature of Pluronic® L61 solubility would allow for flexibility in the manufacturing process. For example, if the temperature of the alkaline barrier slurry exceeds the upper specification at any point during the manufacturing process one could, in theory, reduce the temperature of the batch and recover the Pluronic® L61 from the filters.

### Example 4

The next step was to apply these learnings to the manufacturing of the alkaline barrier slurry SVM product. Apparatus to maintain <23° C. slurry temperature during manufacturing and packaging is not available. The next best option is to chill some chemical constituents in the slurry, that is, a cool process manufacturing.

The components selected were DIW and the abrasive because their combined mass comprises 80% of the total mass of the slurry.

By chilling these components to the target low temperature such as < or =8° C., the heat transfer calculation predicted that the volume of the build would stay below 20° C. from DIW charge to the end of packaging.

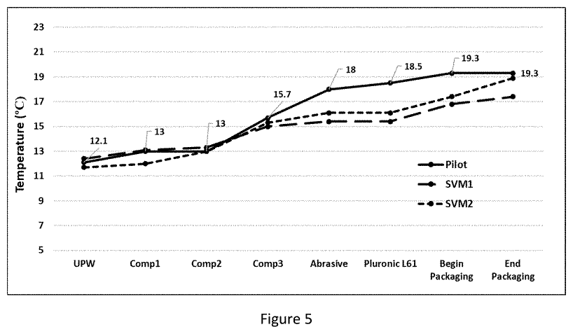

The temperature recordings generated for the four totes slurries made with the “cool” process were shown in FIG. 5.

In FIG. 5, comp 1 to comp 3 each could be any one of pH adjuster, oxidizing agent, corrosion inhibitor, biocide, and chelator.

All four totes slurries had a starting temperature range between 12 and 14° C. and an ending temperature range between 17 and 19° C. demonstrating that this new process can stay below the manufacturing temperature target of 20° C.

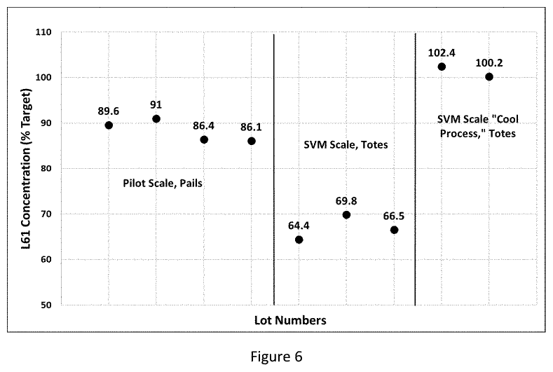

The Pluronic® L61 HPLC data from the cool process manufacturing was overlaid with the data from FIG. 1 and shown in FIG. 6.

As shown in FIG. 6, the modified cool manufacturing process yielded 100% of Pluronic® L61 target.

The foregoing examples and description of the embodiments should be taken as illustrating, rather than as limiting the present invention as defined by the claims. As will be readily appreciated, numerous variations and combinations of the features set forth above can be utilized without departing from the present invention as set forth in the claims. Such variations are intended to be included within the scope of the following claims.

1. A method for making a barrier chemical mechanical planarization polishing composition, comprising:
providing water;
providing at least one constituent selected from the group consisting of pH adjuster, oxidizing agent, corrosion inhibitor, biocide, and chelator;
adding the at least one constituent into the water to obtain a first mixture, providing abrasive;
providing a block co-polymers surfactant that have a hydrophobic, polypropylene oxide (PO), segment bookended by two hydrophilic polyethylene oxide (EO) segments;
adding the abrasive and the block co-polymers surfactant into the mixture to obtain a second mixture;
filtering the second mixture with filters having a pore size of ≤1 μm, 0.5 μm, or 0.1 μm to obtain the chemical mechanical planarization polishing composition for packaging;
wherein the abrasive and waster are having a low starting temperature to make the block co-polymers surfactant 100% solubilized in the chemical mechanical planarization polishing composition; and
pH of the polishing composition is between 2 to 14, 4 to 12, 9 to about 11.5; or 10 to 11.

2. The method of claim 1, wherein the abrasive is selected from the group consisting of colloidal silica, alumina, ceria, germania, silica, titania, zirconia, alumina dopes colloidal silica in lattices, organic polymer particles, composite particles of inorganic and organic particles, surface modified inorganic/organic particles, and combinations thereof.

3. The method of claim 1, wherein the oxidizing agent is selected from the group consisting of hydrogen peroxide, periodic acid, potassium iodate, potassium permanganate, ammonium persulfate, ammonium molybdate, ferric nitrate, nitric acid, potassium nitrate, ammonia, amine compounds, and combinations thereof; and in an amount ranging from about 0.05 wt. % to about 10 wt. %; preferably from about 0.5 wt. % to about 2 wt. %.

4. The method of claim 1, wherein the corrosion inhibitor is selected from the group consisting of benzotriazole or benzotriazole derivatives, 3-amino-1,2,4-triazole, 3,5-diamine-1,2,4-triazole, and combinations thereof; and in an amount ranging from about 0.001 wt. % to about 1.0 wt. %; preferably from about 0.01 wt. % to about 0.1 wt. %.

5. The method of claim 1, wherein the chelator is selected from the group consisting of benzosulfonic acid, 4-tolyl sulfonic acid, 2,4-diamino-benzosulfonic acid, and etc., and also non-aromatic organic acids, such as itaconic acid, malic acid, malonic acid, tartaric acid, citric acid, oxalic acid, gluconic acid, lactic acid, mandelic acid, and combinations thereof; and in an amount ranging from about 0.01 wt. % to about 3.0 wt. %; preferably about from 0.4 wt. % to about 1.5 wt. %.

6. The method of claim 1, wherein the pH adjustor selected from the group consisting of (a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and in an amount ranging from about 0.0001 wt. % to about 2 wt. %.

7. The method of claim 1, wherein the abrasive and waster are having the low starting temperature of ≤8° C.
